(19) United States
(12) Patent Application Publication
(10) Pub. No.: US 2020/0274007 A1
(43) Pub. Date: Aug. 27, 2020

(54) COLOR-CONTROLLABLE THIN-FILM SOLAR CELL AND METHOD OF MANUFACTURING THE SAME

(71) Applicant: KOREA INSTITUTE OF SCIENCE AND TECHNOLOGY, Seoul (KR)

(72) Inventors: Jeung Hyun JEONG, Seoul (KR); Kyeong Seok Lee, Seoul (KR); Doh Kwon Lee, Seoul (KR); Won Mok Kim, Seoul (KR); Hyeong Geun Yu, Seoul (KR)

(73) Assignee: KOREA INSTITUTE OF SCIENCE AND TECHNOLOGY, Seoul (KR)

(21) Appl. No.: 16/366,193

(22) Filed: Mar. 27, 2019

(30) Foreign Application Priority Data
Feb. 27, 2019 (KR) 10-2019-0023353

(51) Int. Cl. H01L 31/0216; H01L 31/0224; H01L 31/18

(52) U.S. Cl. CPC H01L 31/02167; H01L 31/02162; H01L 31/022466; H01L 31/1884; H01L 31/022425

(57) ABSTRACT

Provided is a color-controllable thin-film solar cell including a transparent electrode layer disposed on an absorption layer, and color structure patterns disposed on at least parts of the transparent electrode layer.

### CROSS-REFERENCE TO RELATED PATENT APPLICATION

This application claims the benefit of Korean Patent Application No. 10-2019-0023353, filed on Feb. 27, 2019, in the Korean Intellectual Property Office, the disclosure of which is incorporated herein in its entirety by reference.

### BACKGROUND

### 1. Field

The present invention relates to a thin-film solar cell and a method of manufacturing the same and, more particularly, to a color-controllable thin-film solar cell and a method of manufacturing the same.

### 2. Description of the Related Art

In addition to the necessity of replacing limited fossil fuels with new renewable energy sources in terms of energy resources, the necessity of environment-friendly energy sources is currently increasing because of serious environmental problems such as fine dust and climate change due to global warming. The solar cell market, which best meets the necessities, is rapidly growing in USA, Europe, Japan, China, the Middle East, etc. and is mostly focused on large-scale power plants. Therefore, silicon (Si) solar cells, which are highly competitive in terms of a high efficiency and a low price, occupy more than 90% of the total market.

The large-scale power plants have issues about transmission and distribution of produced electricity to provide the electricity to consumers. However, solar cells are easily installable and thus are increasingly being installed in small scales near consumers as distributed power generation systems. In addition, for energy independence of big cities with large populations, buildings require energy saving and energy production systems and thus employment of building-integrated solar cells using roofs, windows, walls, etc. of the buildings is effective. When solar cells are installed near consumers, aesthetic impressions need to be provided to the consumers by controlling colors of solar cell modules.

However, coloring of solar cells means that a specific wavelength band of light is reflected, and thus reduces photovoltaic performance. A color structure using a wavelength-selective reflection and transmission scheme needs to have a very high reflection/transmission selectivity to minimize the reduction in photovoltaic performance. That is, instead of reflecting a wavelength band of a desired color, the other wavelengths need to be transmitted 100%.

FIGS. 5A to 5C are cross-sectional views and a graph of a general thin-film solar cell 400 employing, on a surface thereof, a color structure layer 70a having a wavelength-selective reflection/transmission function. As a representative example, a distributed Bragg reflector (DBR) is used. Multiple dielectric layers need to be stacked on one another (for example, the color structure layer 70a needs to be formed by alternately depositing first dielectric layers 72a and second dielectric layers 74a on one another) to increase reflection/transmission selectivity for every color, and thus increased process cost reduces price competitiveness of the thin-film solar cell 400.

Since different wavelengths of solar light have different intensities, when the color structure technology is used, the intensity of light absorbed into the solar cells varies depending on a color and thus the performance of the solar cells also varies depending on a color. That is, when the solar cells are installed on a building which requires different colors, the solar cells of different colors have different photovoltaic efficiencies and thus aesthetic exterior of the building may not be easily implemented independently of energy output. Therefore, price-competitive solar cells capable of controlling colors thereof independently of energy generation are required.

### SUMMARY

The present invention provides a thin-film solar cell module capable of controlling a color thereof independently of photovoltaic performance, having a high price competitiveness, being easily produced in a large area, and including a color structure that does not cause damage of the solar cell, and a method of manufacturing the same. However, the scope of the present invention is not limited thereto.

According to an aspect of the present invention, there is provided a color-controllable thin-film solar cell.

The color-controllable thin-film solar cell may include a transparent electrode layer disposed on an absorption layer, and color structure patterns disposed on at least parts of the transparent electrode layer.

The color structure patterns may have a stack structure of two or more thin-films having different refractive indices.

The thin-films having different refractive indices may include metal or a dielectric layer.

The color structure patterns may have a first metal/dielectric/second metal structure.

The color structure patterns may be disposed only on the transparent electrode layer not to overlap with pattern lines formed in the transparent electrode layer divided into strips.

The color structure patterns may have a closed shape such as a circular shape or a rectangular shape, or may be disposed in a band shape not parallel with the pattern lines, connected or partially disconnected from end to end of a module, and having a uniform width.

The color structure patterns may be disposed to be parallel with the pattern lines.

The absorption layer may be disposed on a back electrode layer, and the back electrode layer may include a transparent substrate including a transparent electrode layer.

According to another aspect of the present invention, there is provided method of manufacturing a color-controllable thin-film solar cell.

The method may include generating a transparent electrode layer on an absorption layer, and generating color structure patterns on at least parts of the transparent electrode layer.

The method may further include generating a back electrode layer on a substrate, performing a first patterning process for dividing the back electrode layer into strips, and then generating the absorption layer on the divided back electrode layer, generating a buffer layer on the absorption layer, generating a window layer on the buffer layer, and performing a second patterning process for dividing parts of the deposited absorption layer, the buffer layer, and the window layer into strips along pattern lines offset from pattern lines formed by the first patterning process, and then generating the transparent electrode layer on the divided window layer, before the generating of the color structure patterns.

The method may further include performing a third patterning process for dividing parts of the deposited absorption layer, the buffer layer, the window layer, and the transparent electrode layer into strips along pattern lines offset from the pattern lines formed by the second patterning process, after the generating of the color structure patterns.

The generating of the color structure patterns may include generating a color structure layer on a substrate and then providing the color structure layer to face the transparent electrode layer, and transferring at least parts of the color structure layer onto a surface of the transparent electrode layer by irradiating laser beams onto the substrate.

The method may further include generating a release film removable by the laser beams, between the substrate and the color structure layer.

The generating of the color structure patterns may include generating the color structure patterns on the transparent electrode layer based on a thin-film deposition process using a mask.

The generating of the color structure patterns may include generating the color structure patterns on the transparent electrode layer based on a photolithography process using a mask.

### BRIEF DESCRIPTION OF THE DRAWINGS

The above and other features and advantages of the present invention will become more apparent by describing in detail embodiments thereof with reference to the attached drawings in which:

FIGS. 1A and 1B are a cross-sectional view and a plan view of a thin-film solar cell according to an embodiment of the present invention;

FIGS. 2A to 2G are sequential cross-sectional views for describing a method of manufacturing a thin-film solar cell, according to an embodiment of the present invention;

FIGS. 3 and 4 are cross-sectional views for describing a method of generating color structure patterns, according to embodiments of the present invention;

FIGS. 5A and 5B are cross-sectional views of a thin-film solar cell (FIG. 5A) employing a general wavelength-selective reflective/transmissive color structure (FIG. 5B) on a whole surface thereof;

FIG. 5C is a graph comparatively showing reflection spectrums and solar light spectrums of reflected colors;

FIGS. 6A and 6B are cross-sectional views showing shunt losses occurring based on color structure patterns and an order of performing a patterning process;

FIGS. 7A to 7C are a cross-sectional view, a reflectance spectrum graph, and a photographic image of color structure samples according to Experimental example 1 based on thickness variations of an upper metal layer;

FIGS. 8A to 8C are a cross-sectional view, a reflectance spectrum graph, and a photographic image of color structure samples according to Experimental example 2 based on thickness variations of a dielectric layer;

FIGS. 9A to 9C are a cross-sectional view, a reflectance spectrum graph, and a photographic image of color structure samples according to Experimental example 3 based on thickness variations of a dielectric layer; and

FIGS. 10A to 10G are photographic images and a reflectance spectrum graph of color structure samples according to Experimental example 4 based on areas of the color structure samples.

### DETAILED DESCRIPTION

Hereinafter, the present invention will be described in detail by explaining embodiments of the invention with reference to the attached drawings. The invention may, however, be embodied in many different forms and should not be construed as being limited to the embodiments set forth herein; rather, these embodiments are provided so that this disclosure will be thorough and complete, and will fully convey the concept of the invention to one of ordinary skill in the art.

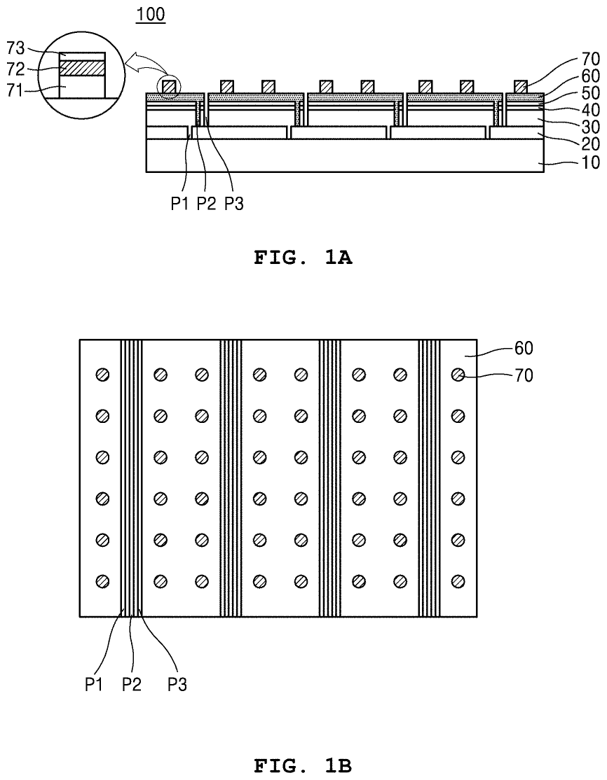

FIGS. 1A and 1B are a cross-sectional view and a plan view of a thin-film solar cell 100 according to an embodiment of the present invention.

Referring to FIG. 1A, in the color-controllable thin-film solar cell 100 according to an embodiment of the present invention, color structure patterns 70 are disposed on only a partial area of the surface of a transparent electrode layer 60 instead of the whole surface thereof. The color structure patterns 70 maximize reflection efficiency of the area to display a color, and allow transmission of light through the other area to perform photovoltaic power generation.

An absorption layer 30 is disposed on a back electrode layer 20 disposed on a substrate 10, and the back electrode layer 20 includes pattern lines formed by a patterning process P1 to divide the back electrode layer 20 into strips. For example, the absorption layer 30 may include Cu(In,Ga)(Se,S)₂, CdTe, or perovskite.

The substrate 10 may use various materials such as glass, metal, and polymer. The back electrode layer 20 may use a material having a high conductivity and being capable of achieving a high corrosion resistance based on a selenization process or the like, e.g., molybdenum (Mo). In some cases, a transparent electrode may be used. For example, the transparent electrode may use transparent conductive oxide such as indium tin oxide (ITO), fluorine-doped tin oxide (FTO), aluminum-doped zinc oxide (AZO), or gallium doped zinc oxide (GZO).

At least parts of not only the absorption layer 30 but also a buffer layer 40 and a window layer 50 disposed on the absorption layer 30 are divided into strips by using pattern lines formed by a patterning process P2 to be offset from the pattern lines formed by the patterning process P1. Herein, the buffer layer 40 and the window layer 50 may be selected as types and configurations based on the type of the absorption layer 30, or be omitted.

The transparent electrode layer 60 cut along pattern lines formed by a patterning process P3 to be adjacent to the pattern lines formed by the patterning process P2 is disposed on the window layer 50, and the color structure patterns 70 are disposed on at least parts of the transparent electrode layer 60. The transparent electrode layer 60 may include transparent conductive oxide like the material used for the back electrode layer 20.

Referring to FIG. 1B, the color structure patterns 70 may have a closed shape such as a circular shape or a rectangular shape, or may be disposed in a band shape not parallel with the pattern lines formed by the patterning process P1, connected or partially disconnected from end to end of a module, and having a uniform width.

For example, the color structure patterns 70 may be disposed only on the transparent electrode layer 60 not to overlap with or to be parallel with the pattern lines formed in the transparent electrode layer 60 divided into strips.

Referring to a magnified part of FIG. 1A, the color structure patterns 70 may have a stack structure of two or more thin-films having different refractive indices, and include, for example, metal or a dielectric layer. In the present invention, to maximize reflection efficiency, the color structure patterns 70 may include a structure in which a dielectric layer 72 and a second metal layer 73 are sequentially stacked on a first metal layer 71.

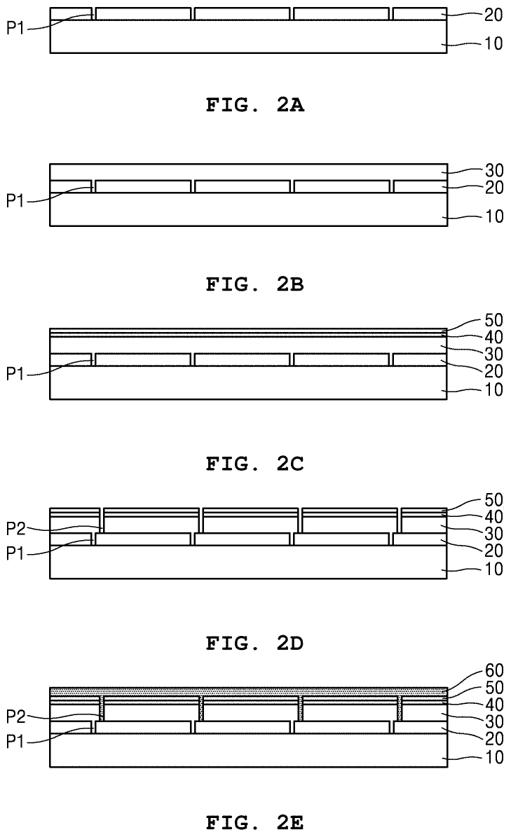

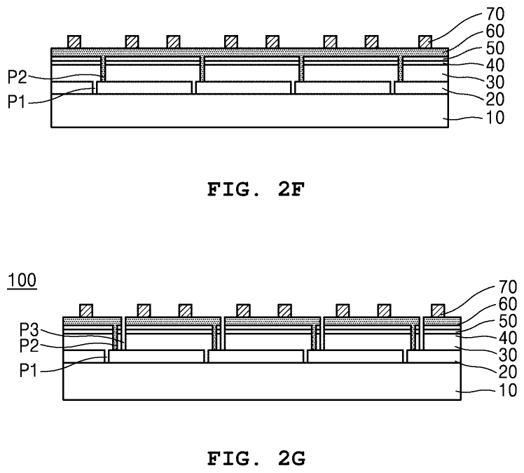

FIGS. 2A to 2G are sequential cross-sectional views for describing a method of manufacturing the thin-film solar cell 100, according to an embodiment of the present invention.

Referring to FIGS. 2A and 2B, the back electrode layer 20 may be formed on the substrate 10, the patterning process P1 may be performed to divide the back electrode layer 20 into strips, and then the absorption layer 30 may be formed thereon. Herein, the absorption layer 30 may use a chalcogenide-based material, perovskite, or amorphous silicon (a-Si).

Referring to FIGS. 2C and 2D, the buffer layer 40 and the window layer 50 may be sequentially formed on the absorption layer 30. Thereafter, the patterning process P2 is performed to divide parts of the deposited absorption layer 30, the buffer layer 40, and the window layer 50 into strips along pattern lines offset from pattern lines formed by the patterning process P1.

Referring to FIGS. 2E to 2G, the transparent electrode layer 60 may be formed on the window layer 50 divided by the patterning process P2. The color structure patterns 70 may be formed on at least parts of the transparent electrode layer 60, and the patterning process P3 may be performed to divide parts of the deposited absorption layer 30, the buffer layer 40, the window layer 50, and the transparent electrode layer 60 into strips along pattern lines offset from pattern lines formed by the patterning process P2, thereby manufacturing the thin-film solar cell 100.

Herein, the patterning process P3 may be performed by irradiating laser beams onto the transparent electrode layer 60 toward the substrate 10. However, to prevent damage of the color structure patterns 70 or incomplete removal of the transparent electrode layer 60 and emitter damage, the laser beams are irradiated from a direction opposite to a surface of the substrate 10 on which the back electrode layer 20 is formed. In this case, the back electrode layer 20 may use a transparent electrode and the laser beams may have a wavelength band absorbable into the absorption layer 30 in a pulse width range of 1 picosecond (ps) to 50 nanoseconds (ns), and preferably, a wavelength band absorbable into the absorption layer 30 in a pulse width range of 10 ps to 10 ns.

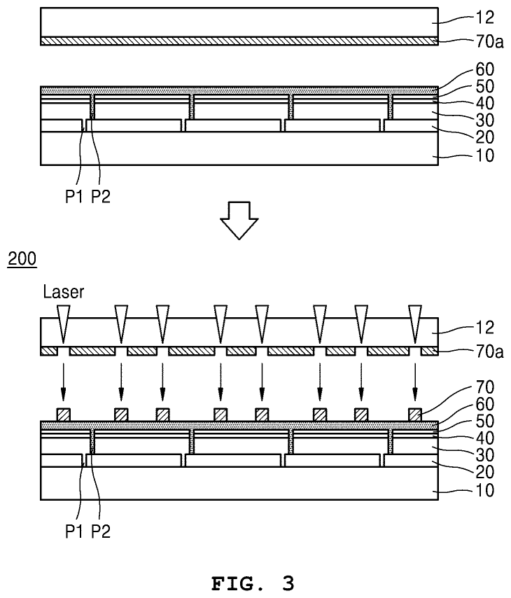

The color structure patterns 70 may be formed using various methods. For example, as illustrated in FIG. 3, the color structure patterns 70 may be formed by generating a color structure layer 70a on a transparent substrate 12, irradiating laser beams onto the substrate 12 to locally heat and lift parts of the color structure layer 70a, and transferring the color structure layer 70a onto the transparent electrode layer 60 of a solar cell module 200 facing the color structure layer 70a.

When the color structure layer 70a is transferred using the laser beams, the color structure layer 70a having a multi-layer structure may be transferred by a single process, or the first metal layer 71 (see FIG. 1A), the dielectric layer 72 (see FIG. 1A), and the second metal layer 73 (see FIG. 1A) may be sequentially transferred.

When the transfer method is used, a diameter of the color structure patterns 70 may be controlled by adjusting a diameter of the laser beams in a range of several μm to several hundred μm, and a large-area process may be appropriately performed. Compared to a multi-layer thin-film structure including only a dielectric, the color structure patterns 70 including metal like a metal/dielectric/metal structure may be appropriate for a transfer process using laser beams. The structure including metal is resistant against damage due to impact occurring during the laser beam transfer process, and the metal is tightly adhered to a target surface to increase an interfacial bonding strength of the color structure patterns 70.

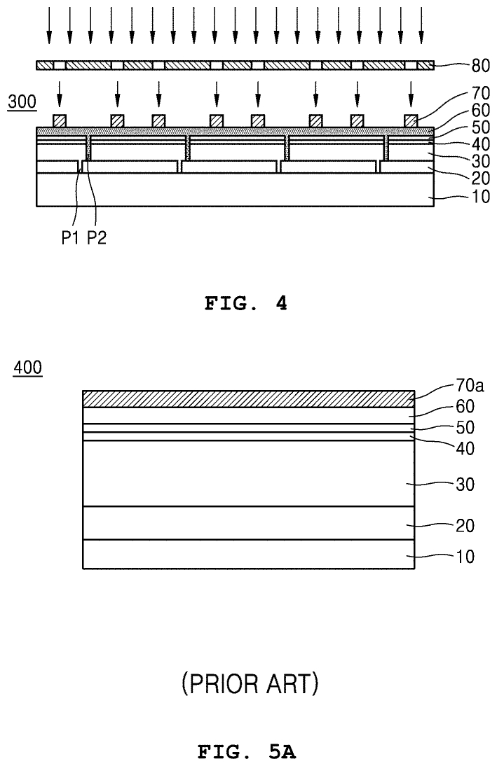

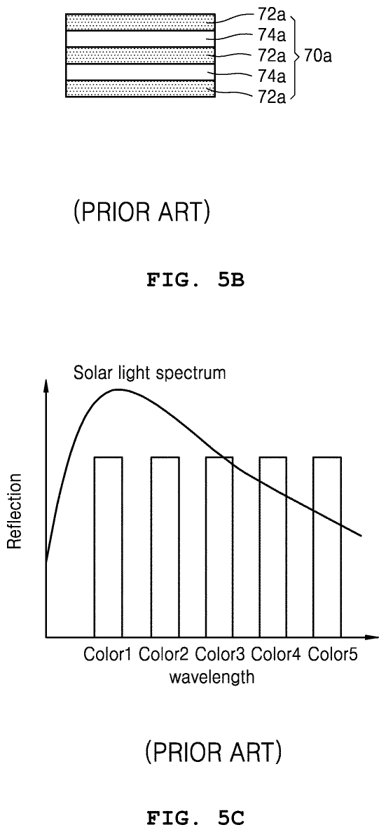

As another example, as illustrated in FIG. 4, the color structure patterns 70 may be formed based on a thin-film deposition process using a mask 80 having a desired shape. In this case, the mask 80 may have openings in regions corresponding to the color structure patterns 70, and the color structure patterns 70 may be formed on the transparent electrode layer 60 by using a material of the color structure patterns 70 as a deposition source. When the color structure patterns 70 have a stack structure of a plurality of material layers, the thin-film deposition process may be performed a number of times corresponding to the number of material layers.

As another example, the color structure patterns 70 may be formed based on a photolithography process. Herein, the photolithography process is a process of generating the color structure layer 70a, generating patterns thereon by using a photosensitive layer, and selectively etching the color structure layer 70a by using the patterns as the mask 80. The photolithography process is a microstructure generation process well known in the art and thus a detailed description thereof will not be provided herein.

As another example, the color structure patterns 70 may be formed by selectively coating a release film on the transparent electrode layer 60, generating a color structure layer on the release film, and then removing the release film.

In the present invention, the color structure patterns 70 and an order of performing the patterning process P3 are very significant factors. In general, in a large-area process, the color structure patterns 70 may not be easily formed to avoid dead zones. Herein, the dead zones are areas which are formed by the patterning processes P1, P2, and P3 to separate cells and on which photovoltaic power generation is not performed.

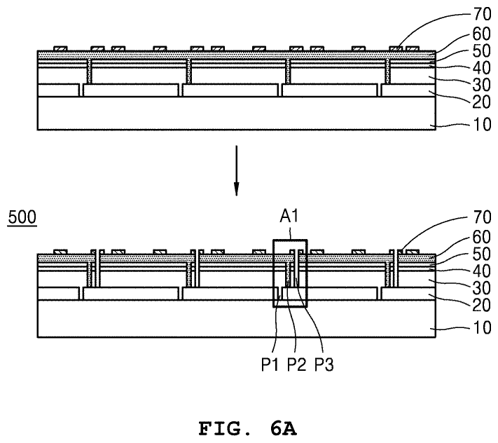

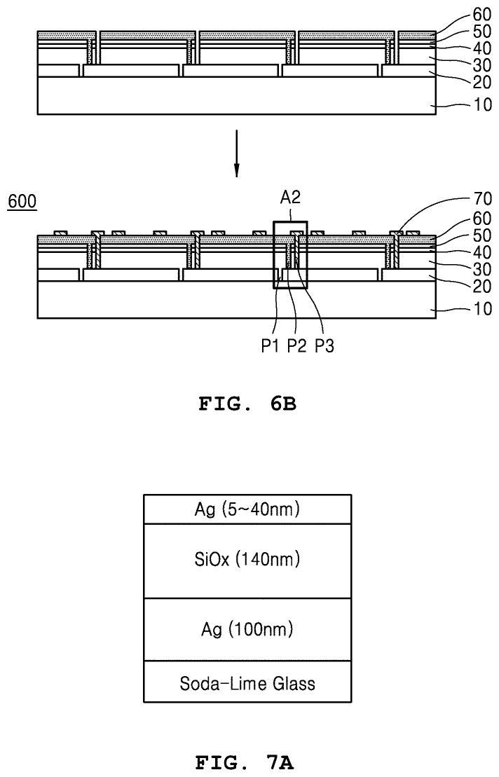

For example, as illustrated in FIG. 6A, when the color structure patterns 70 are located on pattern lines formed by the patterning process P3, parts of the color structure patterns 70 (see A1) may be removed in the patterning process P3 and thus shunt loss may occur near the pattern lines formed by the patterning process P3.

As another example, as illustrated in FIG. 6B, when the patterning process P3 is performed and then the color structure patterns 70 are formed on pattern lines formed by the patterning process P3 (see A2), the color structure patterns 70 serve as shunt paths between adjacent cells.

Therefore, as illustrated in FIGS. 2F and 2G, when the color structure patterns 70 are formed on the transparent electrode layer 60 and then laser beams are irradiated onto the substrate 10 to remove the absorption layer 30 and the transparent electrode layer 60 at a time, leakage current between cells due to the color structure patterns 70 may be prevented.

For example, as illustrated in FIG. 1A, the color structure patterns 70 may have a three-layer structure of the first metal layer 71/the dielectric layer 72/the second metal layer 73. In this case, the first and second metal layers 71 and 73 may use metal such as silver (Ag), aluminum (Al), titanium (Ti), or molybdenum (Mo), and the dielectric layer 72 may use oxide such as SiOx or TiOx, or nitride. Reflection intensity, reflected color, transmission intensity, and transmitted color may be variously controlled by adjusting thicknesses of the first metal layer 71, the dielectric layer 72, and the second metal layer 73.

Experimental examples will now be described to promote understanding of the present invention. However, the following Experimental examples are merely to promote understanding of the present invention and the present invention is not limited thereto. Color structure samples for tests are manufactured under various conditions.

### Experimental Example 1

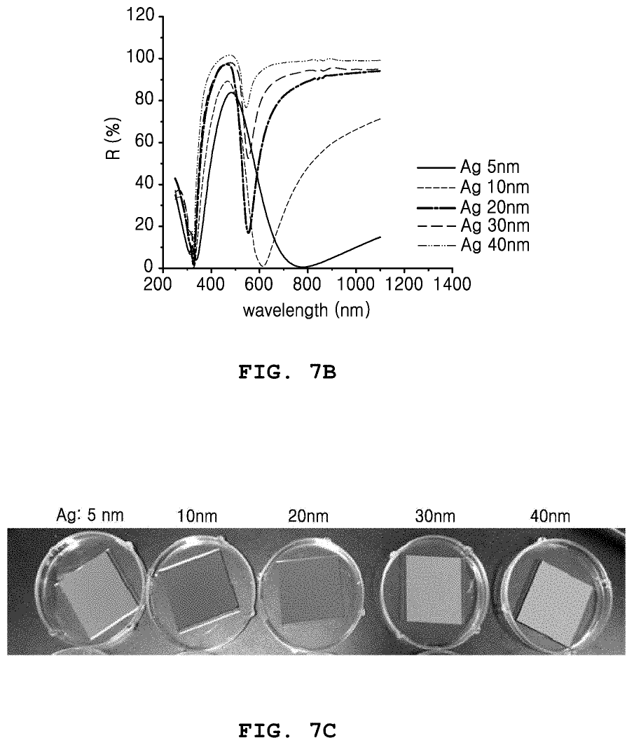

Referring to FIG. 7A, a soda-lime glass substrate is used as a substrate for generating a color structure sample. The color structure sample is formed by depositing Ag on the glass substrate to a thickness of 100 nm based on sputtering, depositing SiOx to a thickness of 140 nm, and then depositing Ag thereon. To increase interfacial bonding strength at glass/Ag and Ag/SiOx interfaces, a Ti thin-film of 2 nm to 5 nm is applied to each interface. In this case, upper Ag is deposited to different thicknesses of 5 nm, 10 nm, 20 nm, 30 nm, and 40 nm. As shown in FIGS. 7B and 7C, when the thickness of upper Ag is 10 nm, the best color selectivity is observed in the reflectance spectrum graph and the vividest color is displayed.

### Experimental Example 2

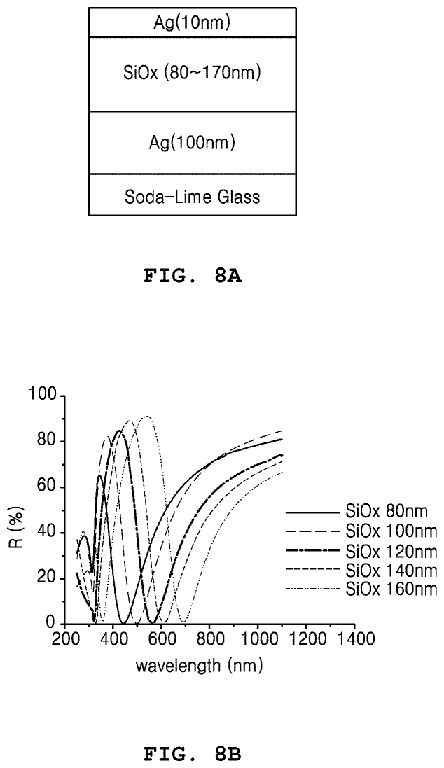

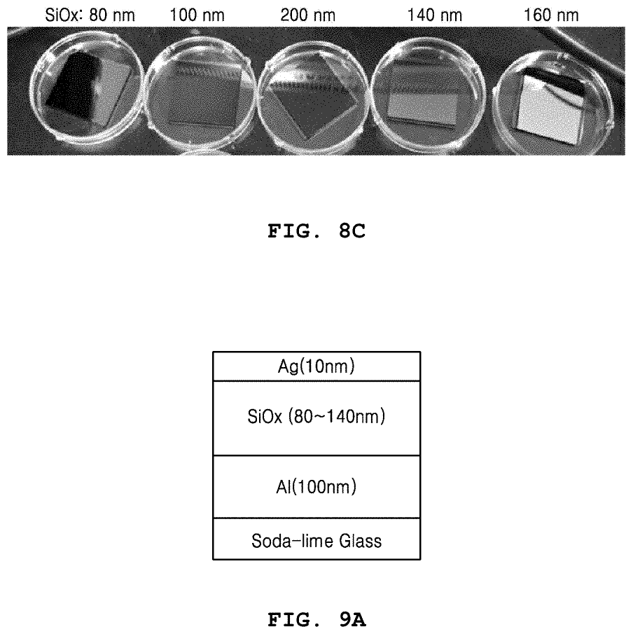

Referring to FIG. 8A, a soda-lime glass substrate is used as a substrate for generating a color structure sample. The color structure sample is formed by depositing Ag on the glass substrate to a thickness of 100 nm based on sputtering, depositing SiOx, and then depositing Ag thereon to a thickness of 10 nm. To increase interfacial bonding strength at glass/Ag and Ag/SiOx interfaces, a Ti thin-film of 2 nm to 5 nm is applied to each interface. In this case, SiOx is deposited to different thicknesses of 80 nm, 100 nm, 120 nm, 140 nm, and 160 nm. As shown in FIGS. 8B and 8C, as the thickness of SiOx is increased, a center wavelength of a reflectance spectrum moves toward a long wavelength and color variations are clearly observed with bare eyes.

### Experimental Example 3

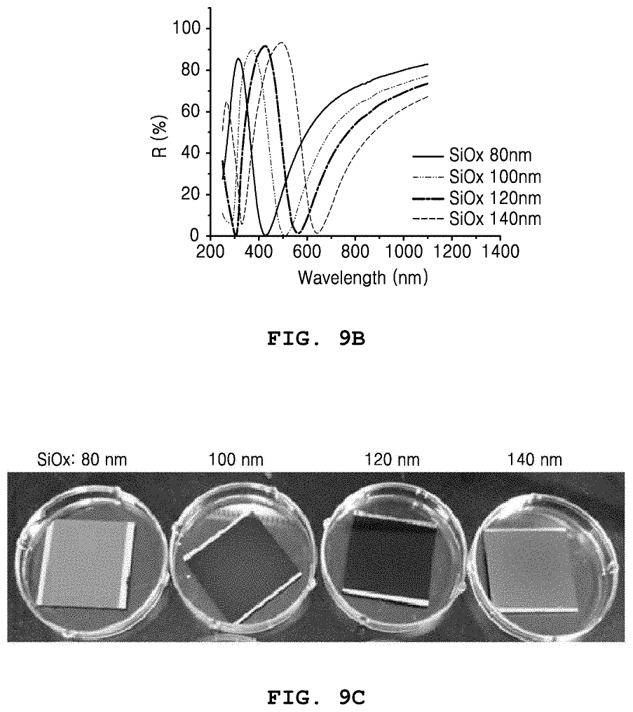

Referring to FIG. 9A, a soda-lime glass substrate is used as a substrate for generating a color structure sample. The color structure sample is formed by depositing Al on the glass substrate to a thickness of 100 nm based on sputtering, depositing SiOx, and then depositing Ag thereon to a thickness of 10 nm. To increase interfacial bonding strength at glass/Ag and Ag/SiOx interfaces, a Ti thin-film of 2 nm to 5 nm is applied to each interface. In this case, SiOx is deposited to different thicknesses of 80 nm, 100 nm, 120 nm, and 140 nm. As shown in FIGS. 9B and 9C, even when lower Ag is replaced by Al, color control similar to the result of Experimental example 2 is enabled.

### Experimental Example 4

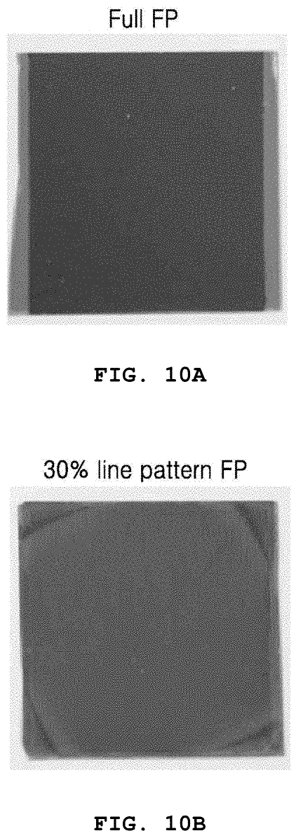

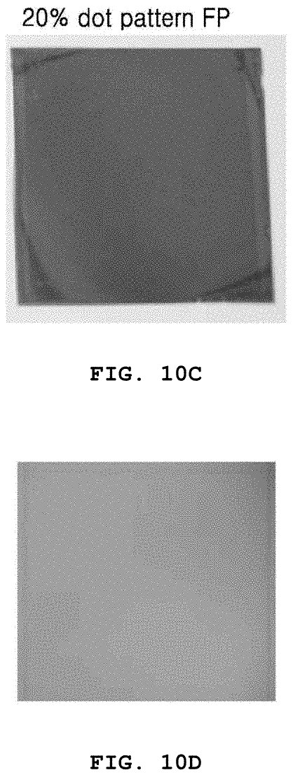

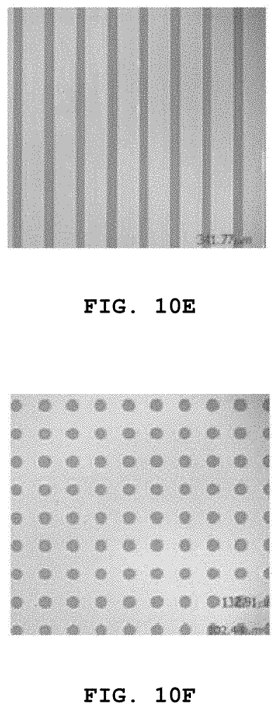

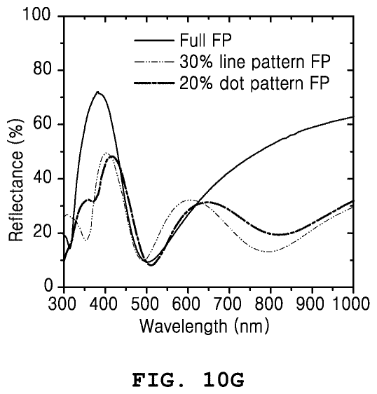

A Si substrate is used as a substrate for generating a color structure sample. The color structure sample is formed by depositing Ag on the Si substrate to a thickness of 100 nm based on sputtering, depositing SiOx to a thickness of 100 nm, and then depositing Ag thereon to a thickness of 10 nm. In FIGS. 10A to 10G, full Fabry-Perot (FP) indicates that a color structure is formed over a whole surface of the Si substrate, 30% line pattern FP indicates linear patterns in which a color structure is formed in an area corresponding to 30% of the surface of the Si substrate, and 20% dot pattern FP indicates circular patterns in which a color structure is formed in an area corresponding to 20% of the surface of the Si substrate.

Referring to FIGS. 10A to 10F, even when the color structures are formed as linear and circular patterns in areas corresponding to 30% and 20% of the surface of the Si substrate, although intensities are lower than that of the sample in which the color structure is formed over the whole surface, highly aesthetic colors may be displayed (FIGS. 10A to 10C are photographic images of the color structure samples, and FIGS. 10D to 10F are optical microscopic images of the color structure samples). As shown in FIG. 10G, strong reflection peaks are observed in the reflectance spectrum graph.

According to the present invention, by designing a color structure based on the above-described method of manufacturing a color-controllable thin-film solar cell, a color-controllable thin-film solar cell capable of displaying various colors, of maximizing reflection efficiency to display a color by using a limited area, and of performing photovoltaic power generation in the other area independently of color control may be manufactured. However, the scope of the present invention is not limited to the above-described effect.

While the present invention has been particularly shown and described with reference to embodiments thereof, it will be understood by one of ordinary skill in the art that various changes in form and details may be made therein without departing from the scope of the present invention as defined by the following claims.

What is claimed is:

1. A color-controllable thin-film solar cell comprising:
a transparent electrode layer disposed on an absorption layer; and
color structure patterns disposed on at least parts of the transparent electrode layer.

2. The color-controllable thin-film solar cell of claim 1, wherein the color structure patterns have a stack structure of two or more thin-films having different refractive indices.

3. The color-controllable thin-film solar cell of claim 2, wherein the thin-films having different refractive indices comprise metal or a dielectric layer.

4. The color-controllable thin-film solar cell of claim 1, wherein the color structure patterns are disposed only on the transparent electrode layer not to overlap with pattern lines in the transparent electrode layer divided into strips.

5. The color-controllable thin-film solar cell of claim 4, wherein the color structure patterns are disposed in a band shape not parallel with the pattern lines, connected or partially disconnected from end to end of a module, and having a uniform width.

6. The color-controllable thin-film solar cell of claim 4, wherein the color structure patterns are disposed to be parallel with the pattern lines.

7. The color-controllable thin-film solar cell of claim 1, wherein the absorption layer is disposed on a transparent substrate comprising a transparent electrode layer.

8. A method of manufacturing a color-controllable thin-film solar cell, the method comprising:
forming a transparent electrode layer on an absorption layer; and
forming color structure patterns on at least parts of the transparent electrode layer.

9. The method of claim 8, further comprising:
forming a back electrode layer on a substrate;
performing a first patterning process for dividing the back electrode layer into strips, and then generating the absorption layer on the divided back electrode layer;
forming a buffer layer on the absorption layer;
forming a window layer on the buffer layer; and
performing a second patterning process for dividing parts of the deposited absorption layer, the buffer layer, and the window layer into strips along pattern lines offset from pattern lines formed by the first patterning process, and then generating the transparent electrode layer on the divided window layer,
before the generating of the color structure patterns.

10. The method of claim 9, further comprising performing a third patterning process for dividing parts of the deposited absorption layer, the buffer layer, the window layer, and the transparent electrode layer into strips along pattern lines offset from the pattern lines formed by the second patterning process, after the forming of the color structure patterns.

11. The method of claim 10, wherein the third patterning process is performed by irradiating laser beams having a wavelength band absorbable into the absorption layer, from a direction opposite to a surface of the substrate on which the absorption layer is formed.

12. The method of claim 8, wherein the forming of the color structure patterns comprises:
forming a color structure layer on a substrate and then providing the color structure layer to face the transparent electrode layer; and
transferring at least parts of the color structure layer onto a surface of the transparent electrode layer by irradiating laser beams onto the substrate.

13. The method of claim 11, further comprising forming a release film removable by the laser beams, between the substrate and the color structure layer.

14. The method of claim 8, wherein the forming of the color structure patterns comprises forming the color structure patterns on the transparent electrode layer based on a thin-film deposition process using a mask.

15. The method of claim 8, wherein the forming of the color structure patterns comprises forming the color structure patterns on the transparent electrode layer based on a photolithography process using a mask.
